(19) United States
(12) Patent Application Publication
(10) Pub. No.: US 2024/0232481 A9
(43) Pub. Date: Jul. 11, 2024

(54) MONITORING AND PREDICTING THE OPERATION OF A PUMP ARRANGED IN A TANK FOR TRANSPORTING A LIQUID PRODUCT ON BOARD A VESSEL

(71) Applicant: GAZTRANSPORT ET TECHNIGAZ, Saint-Remy-Les-Chevreuse (FR)

(72) Inventors: Alaric Sibra, Saint-Remy-Les-Chevreuse (FR); Erwan Corbineau, Saint-Remy-Les-Chevreuse (FR)

(21) Appl. No.: 18/546,353

(22) PCT Filed: Feb. 23, 2022
(86) PCT No.: PCT/EP2022/054547

§ 371 Date: Aug. 14, 2023

(30) Foreign Application Priority Data
Feb. 26, 2021 (FR) 2101926

(51) Int. Cl. G06F 30/28; F17C 13/02

(52) U.S. Cl. CPC G06F 30/28; F17C 13/02; F17C 2205/0323; F17C 2221/033; F17C 2227/0135; F17C 2227/0178; F17C 2250/032; F17C 2250/0417; F17C 2270/0105

(57) ABSTRACT

The invention relates to monitoring and predicting the operation of a pump (30) arranged in a tank (3) for transporting a liquid product on board a ship (1), the pump (30) having a pump-head (31) arranged in the tank (3). A tripping risk parameter of the pump (30) is estimated at least as a function of a required net positive suction head of the pump (30), of the current filling level of the tank and of a current state of movement, which is a current sea state and/or a current state of movement of the ship, and a user is provided with an indication as a function of said tripping risk parameter.

A particular application to ships for transporting a cold liquid product, more particularly to ships for transporting LNG of the type which consume the boil-off gas for their propulsion.

### TECHNICAL FIELD

The invention relates to monitoring and predicting the operation of a pump arranged in a tank for transporting a liquid product on board a ship, in particular a sealed and thermally insulating tank for transporting a cold liquid product such as a liquefied gas, especially liquefied natural gas.

### TECHNOLOGICAL BACKGROUND

Sealed and thermally insulating tanks are widely used for storing and/or transporting liquefied gas at low temperature, such as tanks for transporting liquefied petroleum gas (also known as LPG) having, for example, a temperature of between −50° C. and 0° C., or for transporting liquefied natural gas (LNG) at about −162° C., under atmospheric pressure. These tanks may be intended to transport liquefied gas and/or to receive liquefied gas which is used as fuel for propulsion of the floating structure. Numerous liquefied gases may also be envisioned, especially methane, ethane, propane, butane, ammonia, dihydrogen or ethylene.

The tanks of the ship may be tanks with a single or double sealing membrane, which allow transport under atmospheric pressure. The sealing membranes are generally made of a thin sheet of stainless steel or Inver. A membrane is generally in direct contact with the liquefied gas.

During its transport, the liquid contained in a tank is subjected to various movements. In particular, the movements of a ship at sea, for example under the effect of climatic conditions such as the state of the sea or the wind, cause agitation of the liquid in the tank. The agitation of the liquid is generally known by the term “sloshing”.

These sloshing phenomena occur on ships transporting and/or using (often referred to as “LNG as Fuel” ships) natural gas, hereafter LNG, or methane carriers as well as on anchored storage ships, referred to as FPSO (“Floating Production Storage & Offloading”), for example an extraction platform and a plant for liquefaction of natural gas, commonly known as FLNG (“Floating Liquefied Natural Gas”), or a floating storage and regasification unit (FSRU), that is to say more generally a floating support for production, storage and exportation.

The aforementioned sealed and thermally insulating tanks are each provided with one or more pumps which, depending on the case, are used to discharge the liquid and/or send a quantity of liquid to an engine. In a manner known per se, each pump has a pump-head intended to suction the liquid toward the top of the tank. In order to suction as much liquid as possible, the pump-head is conventionally arranged in proximity to a lower wall of the tank.

In order to optimize the useful volume of liquid cargo which it is possible to load in the tank and discharge from the tank, the liquid heel, that is to say the volume of liquid which is present in the lower part of the tank when the latter is nearly empty, should have a volume that is a small as possible. When the tank is nearly empty, however, the sloshing may cause the pump-head to be partially or fully no longer covered by liquid. If this happens while the pump is operating, such uncovering of the pump-head may cause the occurrence of cavitation phenomena in the pump and/or “tripping” of the pump. Moreover, cavitation phenomena in the pump and tripping of the pump should be avoided as much as possible because they may degrade or damage the pump, and even the pipes and the fluidic systems connected to the pump.

It has been proposed in the documents EP 1 314 927 A1 and WO 2017/055744 A1 to surround the pump-head with an enclosure or a container, the enclosure or the container having valves for retaining a certain height of liquid around the pump-head and thereby limiting the risk of the pump-head being uncovered.

### SUMMARY

The invention proposes another approach, which consists in automatically monitoring the operation of the pump by estimating a tripping risk parameter of the pump and in providing a user with an indication as a function of the tripping risk parameter. One idea on which the invention is based is thus: to determine parameters relevant for the risk of the pump tripping, inter alia a required NPSH of the pump, a current filling level of the tank and a current state of movement; to estimate a risk of the pump tripping as a function of these parameters; and to provide a user with an indication as a function of the tripping risk parameter. Another idea on which the invention is based is to estimate the tripping risk parameter either on the basis of a simulation of the evolution of the position of the liquid-gas interface inside the tank by a method of computational fluid dynamics (CFD) or with the aid of a predictive model trained by a supervised machine learning method.

According to one embodiment according to a first variant, the invention provides a monitoring method carried out by a computer for monitoring the operation of a pump arranged in a tank for transporting a liquid product on board a ship, the pump having a pump-head arranged in the tank, the monitoring method comprising:
obtaining at least one operating parameter of the pump;
determining a required net positive suction head of the pump as a function of said at least one operating parameter of the pump;
determining a current filling level of the tank;
determining a current state of movement, which is a current sea state and/or a current state of movement of the ship;
estimating a tripping risk parameter of the pump at least as a function of the required net positive suction head of the pump, of the current filling level of the tank and of the current state of movement, which have been determined in this way, and providing a user with an indication as a function of said tripping risk parameter.

By virtue of such a method, a user such as a crew member may undertake any measure necessary for limiting the risk of the pump tripping, if so required, for example slowing or stopping the ship or changing the course of the ship, and therefore reducing the risk of damage to the pump and to the fluidic systems connected to the pump.

Depending on the embodiments, the method described above may have one or more of the following characteristics.

According to one embodiment, the at least one operating parameter of the pump comprises a delivery rate of the pump.

The method is suitable for any positioning of the pump-head in the tank. It does, however, have an advantageous application for pump-heads arranged toward the bottom of the tank. According to one embodiment, the tank has a sump and the pump-head is arranged in said sump. According to one embodiment, the pump-head is arranged in proximity to a lower wall of the tank.

According to one embodiment, the pump-head is arranged in proximity to a lower wall of the tank and the pump-head is accommodated in a container located inside the tank, the container having a bottom which faces toward the lower wall of the tank and is provided with a passage placing the interior of the container in communication with the exterior of the container, an upper portion of the container, opposite the bottom of the container, having an opening in communication with the interior of the tank, the container furthermore having at least one mobile valve arranged to cooperate with a corresponding valve seat carried by the bottom of the container, the valve being capable of obstructing the passage of the bottom of the container when a pressure difference exerted on the valve between the exterior of the container and the interior of the container is less than a determined positive threshold, and of freeing the passage when said pressure difference is greater than said threshold.

Such a container provided with valves tends to ensure that the pump-head is always surrounded by liquid, this liquid being retained in the container by the valve or valves. The container therefore provides additional protection against the risk of the pump tripping. The combination of the container with the method described above therefore makes it possible to greatly reduce the risk of the pump tripping.

According to one embodiment, the tripping risk parameter of the pump is estimated as a function of the required net positive suction head of the pump, of the current filling level of the tank and of the current state of movement, which have been determined in this way, and as a function of at least one among a draft of the ship, a speed of the ship, a heading of the ship and at least one operating parameter of the pump.

According to one embodiment, the step which consists in estimating a tripping risk parameter of the pump comprises:
simulating an evolution of the position of a free surface of the liquid inside the tank by a computational fluid dynamics method;
extracting from the results of the simulation an evolution of a height in the tank of the free surface at the pump-head; and
calculating the tripping risk parameter of the pump as a function of the evolution of said height and of the required net positive suction head of the pump.

According to another embodiment, the step which consists in estimating a tripping risk parameter of the pump is performed with the aid of a predictive model trained by a supervised machine learning method over a training data set, the training data set being obtained on the basis of:
results of a plurality of tests, each test consisting in subjecting a test tank having a given filling level to movements and in measuring a height in the test tank of a free surface of the liquid at the pump-head, and/or
results of simulations, each consisting in simulating, by a computational fluid dynamics method, an evolution of the position of a free surface of the liquid within a tank model which has a given filling level and is subjected to movements, and in extracting from the results of the simulation an evolution of a height in the tank of the free surface of the liquid at the pump-head.
   According to one embodiment, the training data set is obtained exclusively on the basis of such results of simulations. This is particularly advantageous because simulations by a computational fluid dynamics method are faster and less expensive to perform than tests on a test tank. It is therefore possible to train the predictive model over more data points, which improves the quality of the prediction of the tripping risk. Furthermore, such simulations allow properties of the liquid which may be difficult to reproduce in a test tank, for example a very low temperature, to be taken into account better.

A “supervised machine learning method” means a machine learning method (also known by the terms artificial learning or statistical learning) which consists in learning a prediction function on the basis of annotated examples. In other words, a supervised machine learning method allows the construction of a model capable of prediction on the basis of a plurality of examples for which the solution to be predicted is known. A supervised machine learning method is typically carried out by a computer.

Owing to its training by a supervised machine learning method over a training data set, the predictive model is capable of estimating by calculation a tripping risk parameter of the pump at least as a function of a required net positive suction head of the pump, of a filling level of the tank and of a current sea state and/or a current state of movement of the ship, without having to explicitly simulate the sloshing of the liquid in the tank. The predictive model is capable of carrying out this estimation even for values of the filling level of the tank and for current sea states and/or states of movement of the ship for which no test has been carried out. The predictive model may therefore be used to estimate a tripping risk parameter of the pump under actual conditions of use on a ship.

According to one embodiment, the tripping risk parameter is of the binary type. In other words, the predictive model predicts only whether or not there is a risk of the pump tripping. The predictive model to be trained in the scope of the present invention is then capable of solving a classification problem. Methods for training predictive models of this type by supervised machine learning are well known in the field of machine learning.

According to one embodiment, the tripping risk parameter of the pump comprises one or more quantitative parameters. The predictive model is then capable of solving a regression problem. Methods for training predictive models of this type by supervised machine learning are well known in the field of machine learning.

According to one embodiment, the tripping risk parameter of the pump comprises at least one among:
the occurrence risk of a situation in which a net positive suction head available at the pump-head is less than the required net positive suction head of the pump;
the maximum duration of a situation in which a net positive suction head available at the pump-head is less than the required net positive suction head of the pump;
the number of occurrences of a situation in which a net positive suction head available at the pump-head is less than the required net positive suction head of the pump;
the total time during which a net positive suction head available at the pump-head is less than the required net positive suction head of the pump;
an average duration of the situations in which a net positive suction head available at the pump-head is less than the required net positive suction head of the pump;
an occurrence probability of a situation in which a net positive suction head available at the pump-head is less than the required net positive suction head of the pump for a duration greater than a predetermined duration.

According to one embodiment, at least one constraint is imposed on the predictive model during its training by the supervised machine learning method.

Thus, the training of the predictive model may be guided based on elementary physical considerations, for example the absence of a risk of the pump tripping in the event that the filling level of the tank is greater than a certain threshold, and/or based on considerations obtained by practical experience, for example the fact that stronger movements or larger dimensions of the tank may potentially entail a greater risk of the pump tripping. The result of this is that the accuracy of the estimation of the tripping risk parameter by the predictive model is enhanced.

According to one embodiment, the method furthermore comprises a step of aiding the decision intended to reduce the tripping risk parameter of the pump.

According to one embodiment, the predictive model considers a plurality of pumps, the predictive model being capable of estimating a tripping risk parameter of each pump as a function of its position inside the ship.

According to one embodiment, the invention furthermore provides a monitoring system for monitoring the operation of a pump arranged in a tank for transporting a liquid product on board a ship, the pump having a pump-head arranged in the tank, the monitoring system comprising:
a command and control unit of the pump, which is capable of obtaining at least one operating parameter of the pump and of determining a required net positive suction head of the pump as a function of said at least one operating parameter of the pump;
at least one filling level sensor for measuring a current filling level of the tank;
a state of movement evaluation device capable of evaluating a current state of movement, which is a current sea state and/or a current state of movement of the ship; and
a processing means configured to estimate a tripping risk parameter of the pump at least as a function of the required net positive suction head of the pump, of the current filling level of the tank and of the current state of movement, which have been determined in this way, and to provide a user with an indication as a function of said tripping risk parameter.

Such a system offers the same advantages as the methods described above.

According to one embodiment, the tank has a sump and the pump-head is arranged in said sump. According to one embodiment, the pump-head is arranged in proximity to a lower wall of the tank.

According to one embodiment, the pump-head is arranged in proximity to a lower wall of the tank and the pump-head is accommodated in a container located inside the tank, the container having a bottom which faces toward the lower wall of the tank and is provided with a passage placing the interior of the container in communication with the exterior of the container, an upper portion of the container, opposite the bottom of the container, having an opening in communication with the interior of the tank, the container furthermore having at least one mobile valve arranged to cooperate with a valve seat carried by the bottom of the container, the valve being capable of obstructing the passage of the bottom of the container when a pressure difference exerted on the valve between the exterior of the container and the interior of the container is less than a determined positive threshold, and of freeing the passage when said pressure difference is greater than said threshold.

According to one embodiment, the tripping risk parameter of the pump is estimated at least as a function of the required net positive suction head of the pump, of the current filling level of the tank and of the current state of movement, which have been determined in this way, and as a function of at least one among a draft of the ship, a speed of the ship, a heading of the ship and at least one operating parameter of the pump.

According to one embodiment according to a second variant, the invention also provides a prediction method carried out by a computer for predicting the operation of a pump arranged in a tank for transporting a liquid product on board a ship, the pump having a pump-head arranged in the tank, the prediction method comprising:
obtaining at least one operating parameter of the pump;
determining a required net positive suction head of the pump as a function of said at least one operating parameter of the pump;
determining a current filling level of the tank;
estimating future states of movement, which are future sea states and/or future states of movement of the ship, on the basis of meteorological information and of a course of the ship;
estimating a tripping risk parameter of the pump at least as a function of the required net positive suction head of the pump and of the current filling level of the tank, which have been determined in this way, of the course of the ship and of the future sea states estimated in this way, and providing a user with an indication as a function of said tripping risk parameter.

According to one embodiment, the at least one operating parameter of the pump comprises a delivery rate of the pump.

According to one embodiment, the tank has a sump and the pump-head is arranged in said sump. According to one embodiment, the pump-head is arranged in proximity to a lower wall of the tank.

According to one embodiment, the pump-head is arranged in proximity to a lower wall of the tank and the pump-head is accommodated in a container located inside the tank, the container having a bottom which faces toward the lower wall of the tank and is provided with a passage placing the interior of the container in communication with the exterior of the container, an upper portion of the container, opposite the bottom of the container, having an opening in communication with the interior of the tank, the container furthermore having at least one mobile valve arranged to cooperate with a valve seat carried by the bottom of the container, the valve being capable of obstructing the passage of the bottom of the container when a pressure difference exerted on the valve between the exterior of the container and the interior of the container is less than a determined positive threshold, and of freeing the passage when said pressure difference is greater than said threshold.

According to one embodiment, the tripping risk parameter of the pump is estimated as a function of the required net positive suction head of the pump and of the current filling level of the tank, which have been determined in this way, and as a function of a draft of the ship and/or of an operating parameter of the pump.

According to one embodiment, the step which consists in estimating a tripping risk parameter of the pump comprises:
simulating an evolution of the position of a free surface of the liquid inside the tank by a computational fluid dynamics method;
extracting from the results of the simulation an evolution of a height in the tank of the free surface at the pump-head; and
calculating the tripping risk parameter of the pump as a function of the evolution of said height and of the required net positive suction head of the pump.

According to another embodiment, the step which consists in estimating a tripping risk parameter of the pump is performed with the aid of a predictive model trained by a supervised machine learning method over a training data set, the training data set being obtained on the basis of:
results of a plurality of tests, each test consisting in subjecting a test tank having a given filling level to movements and in measuring a height in the test tank of a free surface of the liquid at the pump-head, and/or
results of simulations, each consisting in simulating, by a computational fluid dynamics method, an evolution of the position of a free surface of the liquid within a tank model which has a given filling level and is subjected to movements, and in extracting from the results of the simulation an evolution of a height in the tank of the free surface of the liquid at the pump-head.

According to one embodiment, the training data set is obtained exclusively on the basis of such results of simulations.

According to one embodiment, the method furthermore comprises a step of aiding the decision intended to reduce the tripping risk parameter of the pump along the course of the ship.

According to one embodiment, the predictive model considers a plurality of pumps, the predictive model being capable of estimating a tripping risk parameter of each pump as a function of its position inside the ship.

Thus, a user such as a crew member may take the decision to make the ship follow a course that makes it possible to reduce the risk of the pump tripping, and therefore to reduce the risk of damage to the pump and the fluidic systems connected to the pump.

According to one embodiment, the invention also provides a prediction system for predicting the operation of a pump arranged in a tank for transporting a liquid product on board a ship, the pump having a pump-head arranged in the tank, the prediction system comprising:
a command and control unit of the pump, which is capable of obtaining at least one operating parameter of the pump and of determining a required net positive suction head of the pump as a function of said at least one operating parameter of the pump;
at least one filling level sensor for measuring a current filling level of the tank;
a state of movement estimation device capable of estimating future states of movement, which are future sea states and/or future states of movement of the ship, on the basis of meteorological information and of a course of the ship; and
a processing means configured to estimate a tripping risk parameter of the pump at least as a function of the required net positive suction head of the pump and of the current filling level of the tank, which have been determined in this way, of the course of the ship and of the future states of movement, which have been estimated in this way, and to provide a user with an indication as a function of said tripping risk parameter.

The methods and systems described above are applicable to ships transporting any type of liquid product. They do, however, have a particular application to ships for transporting a cold liquid product, especially liquefied gases.

In some embodiments, the tank is a sealed and/or thermally insulating tank.

In some embodiments, the liquid product is a cold liquid product.

In some embodiments, the cold liquid product is a liquefied gas, especially liquefied natural gas (LNG) or liquefied petroleum gas (LPG)

When the liquefied gas is LNG, the ship may be a ship of the type which consumes the boil-off gas (BOG) for its propulsion. Such ships are known per se by the name “LNG-fueled ship” or LFS. The pump is then preferably a pump arranged in the tank so as to be able to send the LNG to one or more engines of the ship for the propulsion of the ship. The methods and systems described above are then particularly useful because the pump is called on to operate regularly during the voyages of the ship.

### BRIEF DESCRIPTION OF THE FIGURES

The invention will be better understood, and further objects, details, characteristics and advantages thereof will become clearer, from the following description of several particular embodiments of the invention, which are given only by way of illustration and without limitation, with reference to the appended drawings.

FIG. 1 is a schematic representation of a ship for transporting a liquid product, more particularly liquefied natural gas.

FIG. 2 represents a partial view in longitudinal section of one of the tanks of the ship of FIG. 1, the tank having a pump which has a pump-head arranged in the tank, in proximity to a lower wall of the tank.

FIG. 3A represents a schematic perspective view of the pump-head of FIG. 1 accommodated in a liquid retention container.

FIG. 3B represents a plan view of the pump-head and of the container of FIG. 3A, illustrating the fixing of the container to the pump-head, as well as the bottom of the container which has valves for communication between the interior of the container and the exterior of the container.

FIG. 3C represents a partial view in section of the bottom of the container, illustrating a valve of the container of FIG. 3A in an open position.

FIG. 3D represents a partial view in section of the bottom of the container, illustrating a valve of the container of FIG. 3A in a closed position.

FIG. 4 represents a system for monitoring the operation of the pump, the system being integrated in the ship of FIG. 1.

FIG. 5 represents a system for monitoring the operation of the pump according to another embodiment.

FIG. 6 is a schematic representation of a device which can be used to carry out tests on a test tank.

FIG. 7 is a flowchart of a method for obtaining a database which can be used to estimate a tripping risk parameter of a pump.

FIG. 8 is a flowchart representing one method for monitoring the operation of a pump.

FIG. 9 is a flowchart representing another method for monitoring the operation of a pump.

FIG. 10 is a flowchart representing a method for predicting the operation of a pump.

### DESCRIPTION OF THE EMBODIMENTS

The following embodiments are described with reference to a ship having a double hull, which forms a bearing structure in which a plurality of tanks are arranged. In such a bearing structure, the tanks have for example a polyhedral geometry, for example of prismatic shape.

In some embodiments, the tanks are sealed and thermally insulating tanks. Such sealed and thermally insulating tanks are intended for transporting a cold liquid product, for example for transporting liquefied gas, especially liquefied natural gas (LNG). The liquefied gas is stored and transported in such tanks at a low temperature, which requires thermally insulating tank walls in order to keep the liquefied gas at this temperature. Such sealed and thermally insulating tanks also have an insulating barrier, which is anchored on the double hull of the ship and bears a sealed membrane. By way of example, such tanks may be produced according to technologies marketed under the brand names Mark III® or NO96® in the name of the Applicant, or the like. It should, however, be pointed out that the embodiments described below are also applicable to tanks which are suitable for transporting any desired liquid product and which are therefore not necessarily sealed and/or thermally insulating.

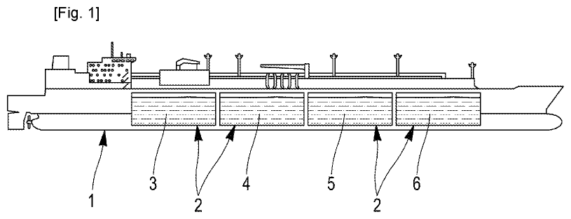

FIG. 1 illustrates a ship 1 having four tanks 2, which in this case are sealed and thermally insulating. The tanks 3, 4, 5, 6 may have identical or different filling states.

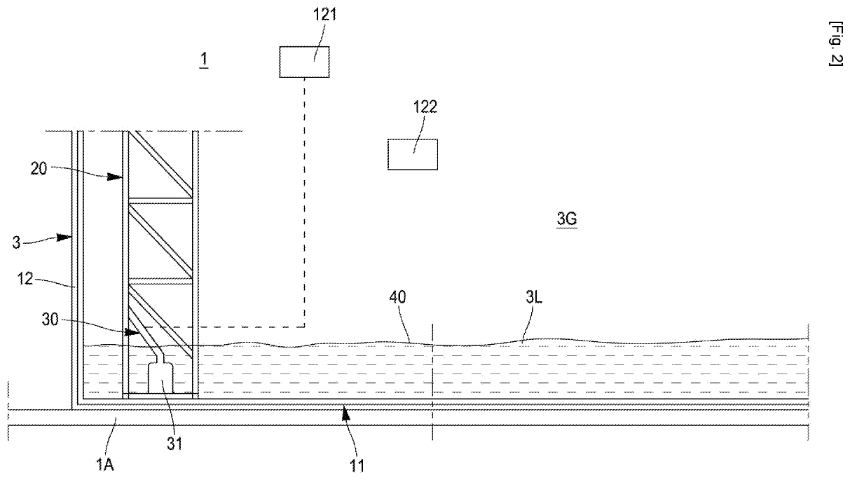

FIG. 2 represents a partial view in longitudinal section of the tank 3 of the ship 1. The double hull of the ship 1 forms a bearing structure 1A on which the walls of the tank 3 are mounted. Each wall of the tank 3 has a multilayer structure successively including a secondary insulating barrier fixed on the bearing structure 1A, a secondary sealed membrane supported by the secondary insulating barrier, a primary insulating barrier covering the secondary sealed membrane and a primary sealed membrane supported by the primary insulating barrier.

A tripod mast 20 is fixed in proximity to a transverse wall 12 of the tank 3. This tripod mast 20 is preferably centered substantially half-way across the width of the ship 1. The tripod mast extends from an upper wall (not represented) of the tank 3 to a bottom wall 11 (also referred to below as the “lower wall”) of the tank 3. The tripod mast 20 supports one or more pump(s) 30, the pump-head 31 of which is located in proximity to the lower wall 11. Pipes connect the pump-head 31 to a cargo handling system (not illustrated) through the upper wall (not represented) of the tank 3. The cargo handling system makes it possible to load/unload the liquid product 3L, here LNG, contained in the tank 3 via the pump 30.

During unloading of LNG 3L from the tank 3, or in the event of using the LNG 3L to supply the engines of the ship 1 with gas, the pump 30 is activated in order to suction the LNG 3L contained in the tank 3 via the pump-head 31. However, in the event that the engines of the ship 1 are supplied with LNG coming from the tank 3 and the ship 1 is making a return voyage, only a liquid heel of LNG 3L is kept in the tank 3 in order to supply the engines of the ship 1 during this return voyage. When it is at sea, moreover, the ship 1 is subjected to numerous movements associated with the sailing conditions. These movements of the ship 1 are imparted to the LNG 3L contained in the tank 3, and thus affect the position of the free surface 40 of the LNG 3L, which free surface 40 constitutes the liquid-gas interface separating the LNG 3L from the gaseous phase 3G contained in the tank 3. It may then happen that the pump-head 31 is partially or fully no longer covered by LNG 3L. If this occurs while the pump 30 is operating, such uncovering of the pump-head 31 may lead to the onset of cavitation phenomena in the pump 30 and/or tripping of the pump 30. Phenomena of cavitation in the pump 30 and tripping of the pump 30 should, however, be avoided as much as possible because they may degrade or damage the pump 30, and even the pipes and the fluidic systems connected to the pump 30. In view of this phenomenon, the ship 1 is provided with a system for monitoring the operation of the pump 30, embodiments of which will now be described below.

Positioning of the pump-head 31 in proximity to the lower wall 11 of the tank 3 is represented in FIG. 2 only by way of nonlimiting example. In some embodiments (which are not represented), the pump-head 31 is arranged in a sump (not represented) which the tank 3 contains. In other embodiments (which are not represented), the pump-head 31 is arranged in an intermediate position in the tank 3, or even in an upper half or upper fourth of the tank 3. The embodiments of the system for monitoring the operation of the pump 30 which are described below are generally suitable for any desired positioning of the pump-head 31 in the tank 3.

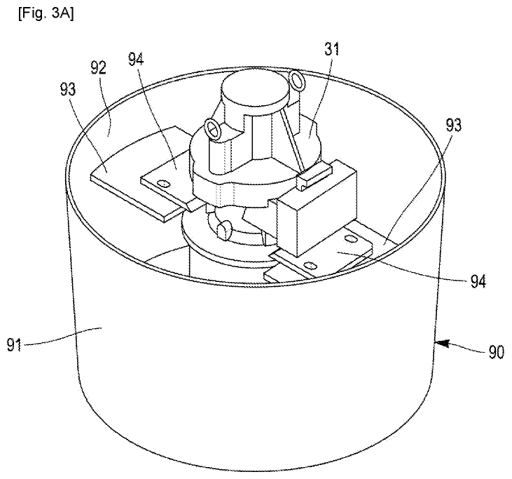

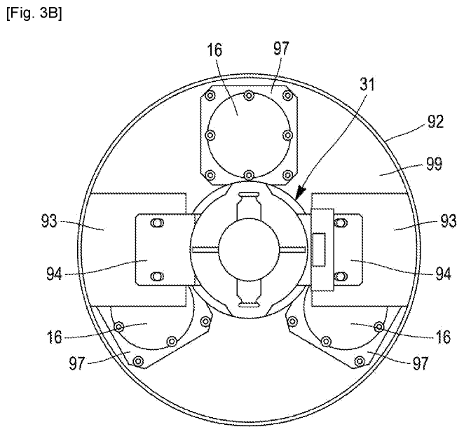

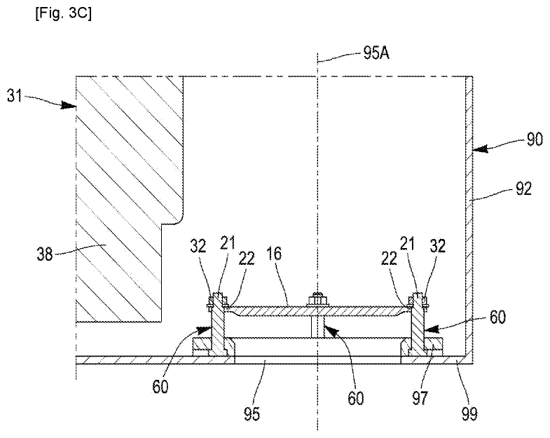

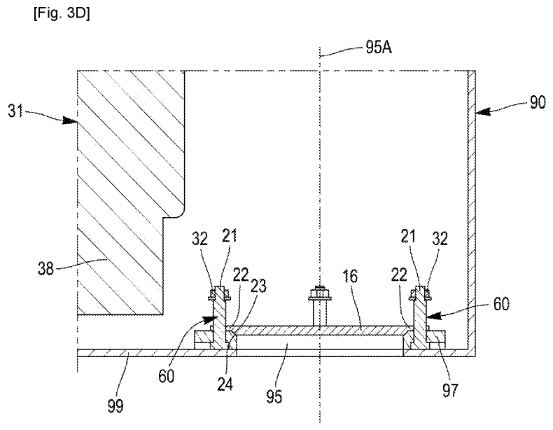

In one particular embodiment, the pump-head 31 is accommodated in a container 90 for retaining LNG 3L, the container 90 being located inside the tank 3. FIGS. 3A to 3D illustrate an embodiment of such a container 90.

FIG. 3A represents a schematic perspective view of the pump-head 31 accommodated in the container 90, so as to illustrate the container 90 and the fixing of said container 90 to the pump-head 31.

The container 90 illustrated in FIG. 3A has a circular cylindrical shape. The container 90 has a bottom 99 (see FIG. 3B) of circular shape, which extends parallel to and above the lower wall 11 of the tank 3. Preferably, the distance between the bottom 99 of the container 90 and the lower wall 11 of the tank 3 is between 25 and 150 mm, although the maximum value may be as much as 250 mm. A circular lateral wall 91 extends from the bottom 99 of the container 90 to the upper wall (not represented) of the tank 3, that is to say moving perpendicularly away from the lower wall 11 of the tank 3, i.e. in a direction parallel to the Earth's gravity.

The upper section of the container 90 does not have a top wall, so that the upper end of the container 90 opposite the bottom 99 of the container is open. Thus, when the level of LNG 3L in the tank 3 lies above the container 9, the container 9 is filled with LNG 3L.

An internal face 92 of the wall 91 has two tabs 93 protruding radially toward the interior of the container 9. These tabs 93 extend from diametrically opposite zones of the internal face 92. The pump-head 31 has two shoulders 94 protruding radially outward, that is to say in the direction of the internal face 92 of the container. The tabs 93 of the container 90 are fixed on the shoulders 94 of the pump-head 31 by any suitable means, for instance with the aid of screws and nuts, welding, or the like. Thus, the container 90 is fixed to the pump-head 31 and said pump-head 31 is accommodated inside said container 90. Preferably, the pump-head 31 is centered in the container 90.

FIG. 3B represents a plan view of the pump-head 31 and of the container 90, illustrating the fixing of the container 90 to the pump-head 31, as well as the bottom 99 of the container 90 having the valves 16 for communication between the interior of the container 90 and the exterior of the container 90.

In the first embodiment, which is illustrated in FIGS. 3A to 3D, the container 90 has three passages 95 (see FIGS. 3C and 3D) passing through the bottom 99 of the container 90. These passages 95 are distributed equally around the pump-head 31. In addition, the container 90 has three valves 16 which are intended to free or obstruct the passages 95 as a function of the pressure exerted by the LNG 3L contained in the tank 3, as explained below. Each valve 16 has a diameter greater than the diameter of the passage 95 with which it cooperates. Each valve 16 is in addition coaxial with said passage 95 with which it cooperates. Here, the valves 16 have a circular shape.

Each passage 95 is surrounded by an insert 97, which is mounted on the bottom 99 of the container. These inserts 97 have a central through-orifice which continues the corresponding passage 95 of the container 90. In addition, these inserts 97 each form a valve seat which cooperates with a respective valve 16, as explained below with reference to FIGS. 3C and 3D. These inserts 97 are fixed on the bottom 99 of the container 90 by any suitable means, for example with the aid of screws and nuts or by welding.

FIGS. 3C and 3D illustrate the operation of a valve 16 as illustrated in FIG. 3B.

One end 38 of the pump-head 31, through which the LNG 3L is suctioned during the unloading of the tank 3, is preferably located in proximity to the bottom 99 of the container 90 in order to be kept immersed in the LNG 3L contained in the container 90.

The valve 16 is mobile in the container along a displacement axis 95A, which is perpendicular to the bottom 99 of the container 90 and preferably parallel to the Earth's gravity. For this purpose, a guiding system makes it possible to guide and limit the displacement of the valve 16. In the embodiment illustrated in FIGS. 3A to 3D, the guiding system has four pins 60 fixed on the bottom 99 of the container 90 (only three of which are illustrated in FIGS. 3C and 3D). Each pin 60 extends from the bottom 99 of the container 90 toward the interior of the container 90, parallel to the displacement axis 95A of the valve 16. These pins 60 are fixed by any suitable means on the bottom 99 of the container 90, for example by welding. Each pin 60 passes through the insert 97, which for this purpose has four ad hoc holes. An end 21 of each pin 60, opposite the bottom 99, of the container 90 has a threaded section 21 of reduced size.

A peripheral border of the valve 16 has four bores 22. A corresponding pin 60 passes through each bore 22. The valve is thus guided in displacement by its peripheral border sliding along the pins 60. A nut 32 is screwed onto the end 21 of each pin 60. This nut 32 forms a shoulder which blocks the displacement of the valve 16 along the axis 19 between said end 21 and the insert 97.

The valve 16 is mobile in the container under the effect of its own weight and, the case in point, a differential pressure exerted on the valve 16 between the interior of the container 90 and the exterior of the container 90. Thus, when the container 9 is surrounded by LNG 3L present in the tank 3, without the LNG 3L extending beyond the upper end of the container 90 and therefore pouring into the container 9 through said open upper end of the container 90, the valve 16 is subjected on the one hand to an internal pressure caused by the LNG 3L present in the container 90 and, on the other hand, to an external pressure caused by the LNG 3L which is in contact with the valve 16 and is present in the tank 3 while surrounding the container 90. The valve 16 is therefore subjected to a pressure difference which makes it possible to push the valve 16 away from the insert 97 and therefore the valve seat. This differential pressure makes it possible to open the valve when the following equation is satisfied:

Pₜₐₙₖ×S_{lower}+F_{archimedes}>Pᵥₑₛₛₑₗ×Sᵤₚₚₑᵣ+Weightᵥₐₗᵥₑ [Math. 1]

Here, Pₜₐₙₖ represents the pressure exerted by the LNG 3L contained in the tank 3 outside the container 90 on the valve 16, S_{lower} represents the surface of the valve 16 in contact with the LNG 3L contained in the tank 3 outside the container 9, F_{archimedes} represents the buoyant force exerted on the valve 16 by the LNG 3L contained in the tank 3 outside the container 9, Pᵥₑₛₛₑₗ represents the pressure exerted by the LNG 3L contained in the container 90 on the valve 16, Sᵤₚₚₑᵣ represents the upper surface of the valve 16 on which the pressure of the LNG contained in the container 9 is exerted, and Weightᵥₐₗᵥₑ represents the weight of the valve 16. Typically, this equation expresses the fact that the opening of the valve 16, that is to say its movement away from the insert 97 forming the valve seat, depends on the difference in height between the LNG 3L contained in the tank 3 outside the container 90 and the LNG 3L contained in the container 90.

Conversely, when the container 90 is not surrounded by LNG 3L, the only pressure exerted on the valve 16 is that exerted by the LNG 3L contained in the container 90. Under the effect of gravity and the pressure exerted by the LNG 3L contained in the container 90, the valve 16 is therefore pushed toward the bottom 99 of the container 90 and cooperates with the valve seat in order to obstruct the passage 95 in the bottom 95 of the container 90.

The valve 16 is made of a material which has a lower density than metals of the stainless steel type, in order to limit the opening pressure, and is compatible with LNG. By way of example, plastic materials will be favored, preferably polytetrafluoroethylene, also known as Teflon (registered trademark), for example in the form of a PTFE coating or solid material. The valve 16 is therefore light and the weight of the valve interferes only little with its opening under the effect of the pressure exerted by the LNG 3L contained outside the container 90 in the tank 3. A coating of PTFE furthermore imparts good sliding properties to the valve 16, facilitating its displacement in the container 90.

As illustrated in FIGS. 3C and 3D, the lower surface of the valve 16 has a chamfered portion 23. The valve 16 thus has a frustoconical portion, the smallest diameter of which is located in proximity to the bottom 99 of the container 90.

In addition, the insert 97 which forms the valve seat also has a chamfered portion 24. The chamfered portion 24 of the insert 97 is complementary to the chamfered portion 23 of the valve 16, said chamfered portion 24 of the insert 97 having a minimum diameter in proximity to the bottom 99 of the container 90. Typically, the chamfered portion 24 of the insert forms the valve seat with which the valve 16 cooperates in order to obstruct the passage 95. Thus, in the case of a chamfered portion 23 of the valve 16 forming an angle of 45° with the bottom 99 of the container 90, the chamfered portion 24 of the insert 97 also has an angle of 45° with respect to the bottom of the container.

These chamfered portions 23 and 24 offer a large contact surface between the valve seat and the valve 16, thus providing the container 90 with better sealing when the valve 16 obstructs the passage 95. Moreover, the chamfered shape 24 of the valve seat guides the displacement of the valve 16 when the latter is moved in the direction of the bottom 99 of the container 90 in order to obstruct the passage 95.

When the LNG 3L contained in the tank 3 surrounds the container or is displaced toward the container because of the pitching or rolling of the ship 1, the pressure exerted by this LNG 3L contained in the tank 3 on the valve 16 makes it possible to push the valve 16 out of the valve seat. The passage 95 is therefore no longer obstructed and the LNG present in the tank 3 enters the container 90 through the passage 95 located in the bottom 99 of the container. Conversely, when the LNG 3L contained in the tank 3 does not surround the container 90 and does not exert a sufficient pressure on the valve 16 to push it out of the valve seat, the LNG 3L contained in the container 90 is retained in said container by the obstruction of the passage 95 due to the valve 16 cooperating in a leaktight manner with the insert forming the valve seat.

Other geometries for the container 90 and/or for the valves 16 are possible, for example as described in the document WO 2017/055744 A1.

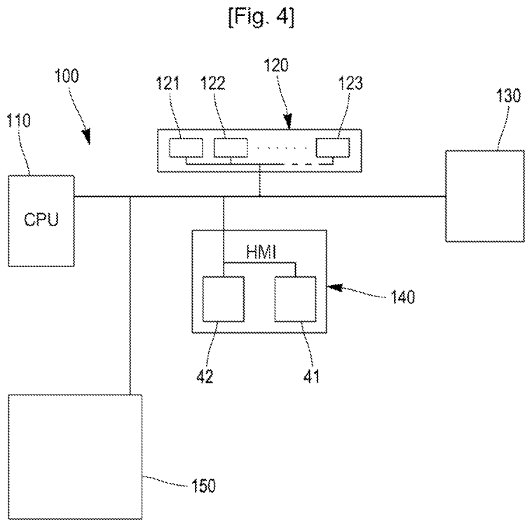

FIG. 4 illustrates an example of a system 100 for monitoring the operation of the pump 30 (referred to below as a “monitoring system 100” or “system 100” for convenience). Here, the monitoring system 100 is on board the ship 1. This monitoring system 100 has a central processing unit 110 connected to a plurality of on-board sensors 120 for obtaining various measurements of parameters. For example, and not exclusively, the sensors 120 thus include a command and control unit 121 of the pump 30 for each pump, at least one filling level sensor 122 for each tank, and a state of movement evaluation device 123. The monitoring system 100 also has a communication interface 130 allowing the central processing unit 110 to communicate with remote devices, for example in order to obtain meteorological data, ship position data or the like.

The command and control unit 121 is configured to determine one or more operating parameters of the pump 30 and to control the operation of the pump 30 as a function of this or these operating parameters and of at least one operational setpoint.

Among the operating parameters of the pump 30, the command and control unit 121 determines at least one required net positive suction head, referred to below as “required NPSH”, of the pump. This quantity is well known per se in the field of pumps. It will merely be reiterated here that the NPSH is a quantity which may be expressed as a pressure or as a liquid column height and that, for a given pump and a given liquid at given conditions of pressure and temperature, distinction is made between the available NPSH and the required NPSH. The available NPSH must be greater than the required NPSH in order to ensure correct operation of the pump, and especially to avoid the onset of a cavitation phenomenon in the pump. The required NPSH depends on the liquid delivery rate that the pump needs to suction, and is provided by the manufacturer of the pump as a function of this liquid delivery rate for given conditions of pressure and temperature. Specifically, the command and control unit 121 can read a setpoint value of the liquid delivery rate that the pump 30 needs to suction and can calculate the corresponding required NPSH by means of a mathematical relationship stored in memory, or can read the corresponding required NPSH from a table stored in memory.

The at least one filling level sensor 122 is configured to measure a current filling level of the tank 3. The current filling level of the tank 3 is measured in the form of a current liquid height in the tank 3 or in the form of a filling percentage of the tank 3 by liquid volume. A plurality of filling level sensors 122, optionally of different types, may be arranged in the tank 3 in order to ensure a certain degree of redundancy.

The state of movement evaluation device 123 determines measured movements of the ship, for example by measuring the accelerations experienced by the ship in translation and rotation according to three orthogonal axes. In order to assess the movements of the ship, it is advantageously possible to use an inertial measurement unit, referred to below as an IMU, which consists of one or more accelerometers and/or one or more gyroscopes, for example mechanical gyroscopes, and/or one or more magnetometers. These measurement units, assuming that a plurality of them are used (of the same type or of two different types), are advantageously distributed over the ship so as to register an accurate measurement of the movement of the ship. It should be noted that an IMU is sometimes commonly referred to as an MRU (“Motion Reference Unit”).

In one alternative, the state of movement evaluation device 123 obtains a current sea state in the vicinity of the ship, for example a height and frequency of the waves in the vicinity of the ship. In one embodiment, for example, the height and/or frequency of the waves are provided on the basis of a visual observation performed by the crew.

The monitoring system 100 furthermore has a human-machine interface 140. This human-machine interface 140 has a display means 41. This display means 41 allows the operator to obtain various items of information, which are calculated by the system, or the measurements obtained by the sensors 120, or even an indication of a tripping risk parameter of a pump, in which case this tripping risk parameter may be estimated as will be described in more detail below.

The human-machine interface 140 furthermore has an acquisition means 42 allowing the operator to provide the central processing unit 110 with quantities manually, typically to provide the central processing unit 110 with data that cannot be obtained by sensors because the ship does not have the required sensor or this sensor is damaged. In one embodiment, for example, the acquisition means allows the operator to input items of information relating to the height and/or frequency of the waves on the basis of a visual observation and/or to input a heading and/or speed of the ship manually.

The monitoring system 100 furthermore has a database 150. This database may be usable to estimate a tripping risk parameter of a pump, as will be described in more detail below.

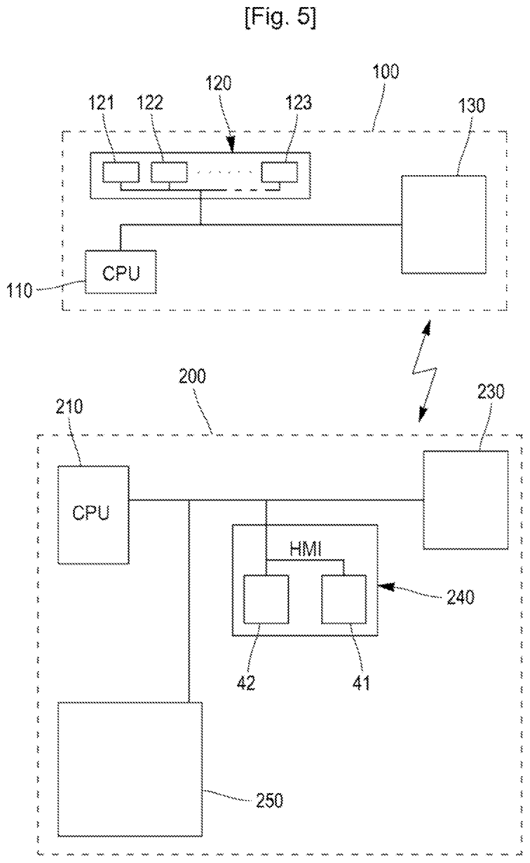

FIG. 5 illustrates an example of a monitoring system 200 which is located onshore and communicates with the ship 1. The ship has the central processing unit 110, the sensors 120 and a communication interface 130. The monitoring system 200 has a central processing unit 210, a communication interface 230, a human-machine interface 240 and a database 250. The way in which the management system 200 operates is similar to the way in which the monitoring system 100 operates, and differs only by the information measured by the sensors 120 of the ship 1 being sent to the onshore monitoring system 200 by means of the communication interfaces 130 and 230. By way of example, the communication interfaces may use terrestrial radiofrequency or satellite data transmission.

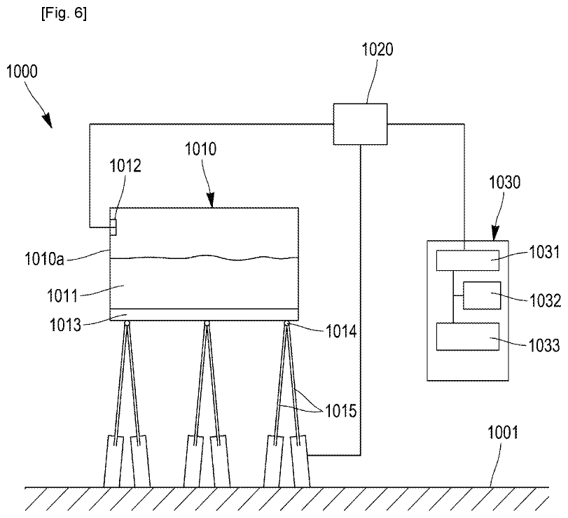

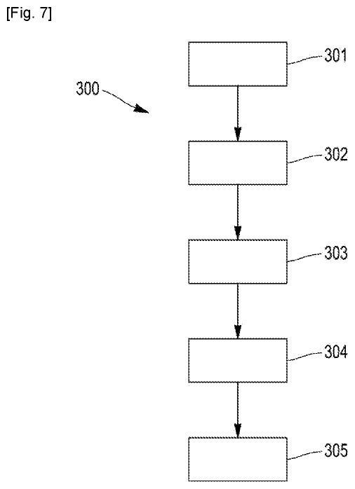

The way in which the database 150 is obtained will now be described with the aid of FIGS. 6 and 7.

FIG. 6 schematically represents an example of a testing device 1000 for carrying out tests on a test tank 1010. The tests consist in subjecting the test tank 1010 to movements, the test tank 1010 having a given filling level of fluid 1011 and, with the aid of at least one level sensor 1012, measuring a height in the test tank of a free surface of the fluid 1011 at the pump-head. The level sensor 1012 may, by way of example, be arranged on a wall 1010a of the test tank 1010. In one variant, the test tank 1010 may actually comprise a pump-head identical to, and arranged in the test tank 1010 at the same position as, the pump-head of the pump whose operation is intended to be monitored. In another variant, the pump-head may be omitted from the test tank 1010: the test then consists in measuring the height of the free surface of the fluid 1011 at the intended position of the pump-head, the latter being considered to be negligible in terms of the evolution of the position of the free surface of the fluid 1011.

The test tank 1010 may have smaller dimensions than the tank intended to receive the pump whose operation is meant to be monitored, and/or may have a geometry representative of this tank.

The fluid 1011 is of course preferably of the same type as the one which is transported by the tank and is intended to be pumped by the pump whose operation is meant to be monitored; it may especially be liquefied petroleum gas (also referred to as LPG) having for example a temperature of between −50° C. and 0° C., or liquefied natural gas (LNG) at about −162° C. under atmospheric pressure. Many liquefied gases may also be envisioned, especially methane, ethane, propane, butane, ammonia, dihydrogen or ethylene. Preferably, the fluid 1011 furthermore has the same or substantially the same liquid/gas density ratio (that is to say the same ratio between the density of the liquid phase and the density of the gaseous phase in equilibrium with the liquid phase) as the fluid transported by the tank, and more preferably the same density and/or the same viscosity, and even more preferably the same temperature as the fluid transported by the tank.

Furthermore, it is possible to measure the level of the free surface of the fluid at a plurality of points in the test tank 1010, the number and arrangement of the level sensors 1012 being adapted accordingly.

As mentioned above, the test tank 1010 is subjected to movements during the tests. In the example represented, the device 1000 thus comprises a platform 1013 to which the test tank 1010 is secured. The platform 1013 is driven in movement by the action of six hydraulic jacks 1015, which are connected at one of their ends to the platform at three fixing points 1014 and at the other end to a framework or to a floor 1001. This makes it possible to drive the test tank 1010 in movement with six degrees of freedom in translation and rotation. The test tank 1010 may of course be driven in movement by different means.

The device 1000 furthermore comprises a test control unit 1020. The test control unit 1020 is configured to control the hydraulic jacks 1015 in order to subject the test tank 1010 to predetermined movements in a test program. In one exemplary embodiment, these movements are movements representative of a given movement of the ship, which preferably take into account the position of the tank on the ship and/or the geometry of the tank. In another exemplary embodiment, these movements are movements representative of a given sea state, which are converted into corresponding movements of the ship, preferably while taking into account the position of the tank on the ship and/or the geometry of the tank. The evaluation of the corresponding movements of the ship on the basis of a given sea state is a familiar task in the evaluation of the seakeeping of a ship. The test control unit 1020 furthermore records the values registered during the test by the at least one level sensor 1012.

The test control unit 1020 communicates with a test data processing unit 1030. The test data processing unit 1030 comprises a communication interface 1031 for receiving from the test control unit 1020 the values registered during the test by the at least one level sensor 1012 as well as the movements imparted to the test tank 1010 during the test. The test data processing unit 1030 furthermore comprises a memory 1033 and a central processing unit 1032.

The test data processing unit 1030 is configured to train a predictive model on the central processing unit 1032, which communicates with the memory 1033, by a machine learning method. The predictive model is capable of estimating a tripping risk parameter of the pump as a function of a required NPSH of the pump, of a filling level of the tank and of a current state of movement, which is a current sea state and/or a current state of movement of the ship.

More particularly, the training of the predictive model is performed by a supervised machine learning method. This training may be performed by the central processing unit 1032 which communicates with the memory 1033.

According to one variant, the predictive model to be trained is capable of estimating a tripping risk parameter of the pump which is of the binary type, that is to say “yes/no”; in other words, the predictive model predicts only whether or not there is a risk of the pump tripping. The predictive model is then capable of solving a classification problem.

According to another variant, the predictive model to be trained is capable of estimating one or more quantitative parameters of the risk of the pump tripping. The predictive model is then capable of solving a regression problem.

By way of example, the tripping risk parameter of the pump may comprise at least one among:
the occurrence risk of a situation in which an NPSH available at the pump-head 31 is less than the required NPSH of the pump 30;
the maximum duration of a situation in which an NPSH available at the pump-head 31 is less than the required NPSH of the pump 30;
the number of occurrences of a situation in which an NPSH available at the pump-head is less than the required NPSH of the pump 30;
the total time during which an NPSH available at the pump-head 31 is less than the required NPSH of the pump 30;
an average duration of the situations in which an NPSH available at the pump-head 31 is less than the required NPSH of the pump 30;
an occurrence probability of a situation in which an NPSH available at the pump-head 31 is less than the required NPSH of the pump 30 for a duration greater than a predetermined duration.

The tripping risk parameter, whether it is of the binary or quantitative type, is in any case estimated for a given period of time.

In one embodiment, the training of the predictive model is performed on the basis of the results of the tests carried out on the test tank 1010. More particularly, in a preferred example, the training of the predictive model is performed on the basis of a tripping risk parameter of the pump which is estimated after each test carried out on the test tank 1010, this tripping risk parameter of the pump being calculated on the basis of the values registered during the test by the at least one level sensor 1012. In one variant, the training of the predictive model is performed both on the basis of the results of the tests carried out on the test tank 1010 and of test data obtained or registered on ships which are operated as a transporter and/or user of liquefied gas, one or more tanks of these ships fulfilling the function of the test tank 1010. In another variant, the training of the predictive model may be performed only on the basis of test data obtained or registered on ships which are operated as a transporter and/or user of liquefied gas, one or more tanks, which are equipped with pumps, of these ships fulfilling the function of the test tank 1010.

In another embodiment, the training of the predictive model is performed not on the basis of the results of the tests carried out on the test tank 1010, but on the basis of results of simulations. More precisely, instead of carrying out tests on the test tank 1010 as just described, an evolution of the position of the free surface of the fluid 1011 within a model of the test tank 1010 is simulated by a method of computational fluid dynamics (CFD), the model of the test tank 1010 being subjected to movements in a similar way as just described; an evolution of the height of the free surface of the fluid 1011 at the pump-head is then extracted from the results of the simulation. Here as well, the simulation may take into account the presence of a pump-head identical to, and arranged in the test tank 1010 at the same position as, the pump-head of the pump whose operation is intended to be monitored, or it may not take into account the presence of the pump-head, the latter being considered to be negligible in terms of the evolution of the free surface of the fluid 1011.

In yet another embodiment, the training of the predictive model is performed both on the basis of results of tests carried out on the test tank 1010 and on the basis of results of simulations, as has just been described.

It should be noted that the simulations may be performed by the central processing unit 1032 which communicates with the memory 1033, or by another computer which communicates its simulation results to the test data processing unit 1030.

A method 300 for obtaining the database 150 will now be described with the aid of FIG. 7. Steps 301 to 305 may be carried out by the central processing unit 1032 which communicates with the memory 1033.

Optionally, the method 300 may comprise a step 301 which consists in excluding, from the training data set used for training the predictive model, results of tests that do not reveal a situation in which an NPSH available at the pump-head 31 is less than the required NPSH of the pump 30. The predictive model is thus trained only on the basis of the data that have revealed a risk of the pump tripping, which improves the accuracy of the estimation of the tripping risk parameter.

After the optional step 301, the method 300 comprises a step 302 which consists in training the predictive model as already described above.

Optionally, at least one constraint is imposed on the predictive model during its training by the supervised machine learning method during step 302. These constraints may be defined on the basis of elementary physical considerations, for example the absence of a risk of the pump tripping in the event that the filling level of the tank is greater than a certain threshold, and/or based on considerations obtained by practical experience, for example the fact that stronger movements or larger dimensions of the tank may potentially entail a greater risk of the pump tripping. The result of this is that the accuracy of the estimation of the tripping risk parameter by the predictive model is enhanced.

At the end of step 302, a predictive model is obtained which is capable of estimating the tripping risk parameter of the pump as a function at least of a filling level of the tank and of a current sea state, and doing so for any values of these quantities, including ones for which no test has been carried out on the test tank 1010 and/or by simulation. However, the calculation required to do this may be too long and/or may require calculation resources that are too great to be able to be implemented on board a ship, for which it is important to obtain an estimate of the tripping risk parameter as quickly as possible and with an on-board system that is as inexpensive as possible. This is why, after step 302, a step 303 is carried out which consists in generating a plurality of input data vectors, each comprising at least one required NPSH of the pump, a current filling level of the tank and a current sea state, followed by a step 304 which, for each input data vector generated in step 303, consists in: obtaining a tripping risk parameter of the pump with the aid of the predictive model obtained in step 302; and storing the tripping risk parameter of the pump in a database in association with the input data vector.

Optionally, in a step 305, the database obtained in step 304 is transmitted to the management system 100 or is stored on a computer-readable recording medium. The database 150, the use of which will be described below, is also obtained.

A case in which the predictive model is capable of estimating the tripping risk parameter of the pump as a function at least of a filling level of the tank and of a current sea state has been described so far. As a variant, however, the predictive model is capable of estimating the tripping risk parameter of the pump as a function of a required NPSH of the pump, of a filling level of the tank and of a current state of movement, which is a current sea state and/or a current state of movement of the ship, and optionally of at least one among a draft of the ship, a speed of the ship, a heading of the ship and at least one operating parameter of the pump.

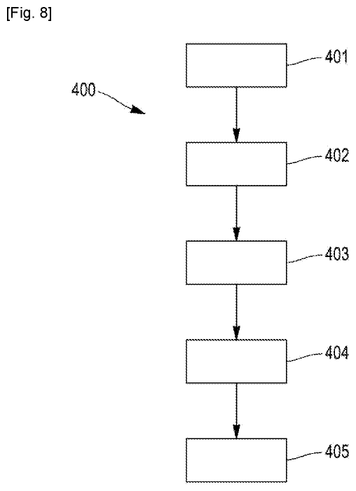

A method 400 for monitoring the operation of a pump with the aid of the predictive model or the database 150 will now be described with the aid of FIG. 8.

According to a first embodiment, the flowchart of FIG. 8 is carried out entirely on the central processing unit 110, which forms the only processing means. According to a second embodiment, the flowchart of FIG. 8 is implemented partially on the onshore management system 200 which communicates with the ship. According to this second embodiment, the ship 1 transmits all the information coming from the sensors 120 to the onshore station, and the central processing unit 110 and the central processing unit 210 together form a divided processing means.

The method 400 comprises a first step 401 which consists in obtaining at least one operating parameter of the pump 30 on the basis of indications provided by the command and control device 121 of the pump 30, and in determining a required NPSH of the pump 30 as a function of this operating parameter or these operating parameters of the pump 30.

The method 400 comprises a second step 402 which consists in determining a current filling level of the tank and a current state of movement. The current filling level of the tank is typically determined on the basis of a filling indication provided by the at least one filling level sensor 122 of the tank. The current state of movement is, as mentioned above, a current state of movement of the ship and/or a current sea state. The current state of movement is determined on the basis of indications provided by the state of movement evaluation device 123. When the current state of movement is a current state of movement of the ship, the indications provided by the state of movement evaluation device 123 may be averaged over an acquisition period, and in view of the fact that an IMU typically has an acquisition frequency much greater than the typical duration of an evolution of the required NPSH of the pump 30. The other data determined in steps 401 and 402 are then also averaged over this same acquisition period.

Optionally, in step 402 a draft of the ship and/or a heading of the ship and/or a speed of the ship is also determined, typically on the basis of indications provided by the on-board systems of the ship. The draft of the ship is typically provided to the on-board systems of the ship by one or more sensors of the float and/or hydrostatic pressure type. The heading of the ship is typically provided to the on-board systems of the ship by one or more navigation compasses. The speed of the ship is typically provided to the on-board systems of the ship by an IMU and/or by a satellite navigation receiver of the GPS type.

After step 402, the method 400 continues to a third step 403 which consists in estimating the tripping risk parameter of the pump 30.

In one variant, this estimation is carried out directly with the aid of the predictive model, which may optionally be stored in a memory associated with the central processing unit 110 or 210.

In another variant, this estimation is carried out by using the database 150. More specifically, an input data vector containing the required NPSH of the pump 30 which was determined in step 401, and the current filling level of the tank and the current state of movement which were determined in step 402, is initially generated. If it is found that the input data vector is present in the database 150, the tripping risk parameter is obtained by simple reading from the database 150. More typically, however, the database 150 will not contain the input data vector but will contain input data similar to those contained in the input data vector. In this figurative case, the tripping risk parameter will be obtained by interpolation of the tripping risk parameter associated with two or more neighboring input data vectors present in the database 150.

After step 403, the method 400 continues to a step 404 which consists in providing a user with an indication as a function of the tripping risk parameter estimated in step 403.

When the tripping risk parameter estimated in step 403 is of the binary type, step 404 may simply consist in providing the user with a warning if the tripping risk parameter is “yes”, or in other words if there is a risk of tripping. The user may, for example, be provided with the warning via the display means 41.

When a tripping risk parameter of the quantitative type is estimated in step 403, step 404 may consist in providing the user with a warning, for example via the display means 41, if the tripping risk parameter exceeds a predetermined threshold. As a variant, step 404 may consist in providing an indication “no tripping risk” if the tripping risk parameter is less than a first threshold, an indication “moderate tripping risk” if the tripping risk parameter is between the first threshold and a second threshold, and an indication “high tripping risk” if the tripping risk parameter exceeds the second threshold. The indications “no tripping risk” and “moderate tripping risk” may be provided via the display means 41, optionally by following a color code and/or in combination with an audible warning. As a variant, any desired number of indications and corresponding thresholds may be adopted.

When a plurality of tripping risk parameters of the quantitative type are estimated in step 403, step 404 may also consist in providing indications “no tripping risk” and “moderate tripping risk” may be provided via the display means 41, optionally by following a color code and/or in combination with an audible warning, as a function of the values taken by the tripping risk parameters.

Preferably, after step 404, the method 400 continues to a step 405 of aiding the decision intended to reduce the tripping risk parameter of the pump 30. This step 405 of aiding the decision may consist in a suggestion to change the direction or route of the ship, a change of heading, which is particularly suitable for stationary floating structures, a modification of the speed of the ship, or a change in the filling level of the tank or tanks (between the tanks or between a tank and a reservoir external to the ship, for the case of a stationary floating structure), or a modification of one or more operating parameters of the pump 30.

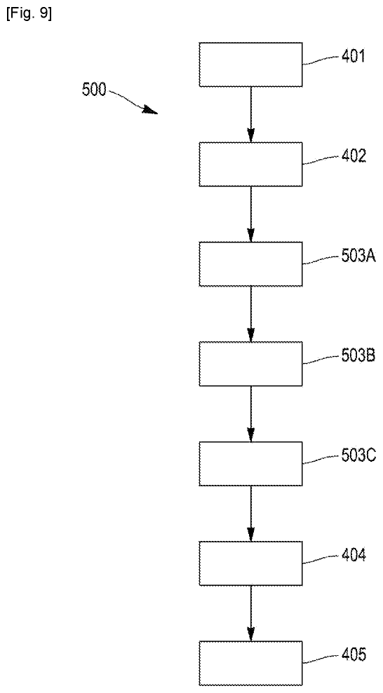

Another method 500 for monitoring the operation of a pump will now be described with the aid of FIG. 9. In this figure, the steps which are identical to those of the method 400 have the same references as in FIG. 8, and are not described in detail again.

The method 500 differs from the method 400 in that the estimation of the tripping risk parameter is not carried out with the aid of the predictive model described above but is carried out directly by simulation using a computational fluid dynamics method. More specifically, after step 401 and 402, which are identical to those described above, the method 500 continues to a step 503A which consists in simulating an evolution of the position of the free surface 40 of the liquid 3L inside the tank 3 by a computational fluid dynamics method. The simulation may be carried out on the basis of a current state of movement of the ship, or on the basis of a current sea state, which is converted into corresponding movements of the ship, or on the basis of a current movement of the ship and a current sea state. As mentioned above, the evaluation of the corresponding movements of the ship on the basis of a given sea state is a familiar task in the evaluation of the seakeeping of a ship. The simulation may take into account the presence of the pump-head 31 in the tank 3 or it may not take into account the presence of the pump-head, the latter being considered to be negligible in the evolution of the position of the free surface 40 of the liquid 3L. The method 500 then continues to step 503B which consists in extracting an evolution of a height in the tank 3 of the free surface 40 at the pump-head 31 from the results of the simulation carried out in step 503A. The method 500 then continues to a step 503C which consists in calculating the risk of the pump 30 tripping as a function of the evolution of the height obtained in step 503B and of the required NPSH of the pump 30, and optionally of other operating parameters of the pump 30. After step 503C, the method continues to steps 404 and optionally 405 which have already been described above.

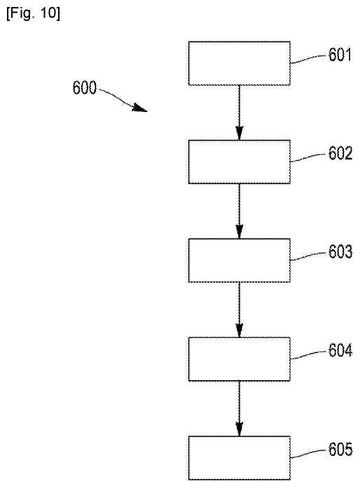

A method 600 for predicting the operation of a pump with the aid of the predictive model or the database 150 will now be described with the aid of FIG. 10. In this variant, the database 150 is obtained on the basis of a predictive model which is capable of estimating a tripping risk parameter of the pump 30 as a function of a required NPSH of the pump, of a filling level of the tank and of a current sea state.

The method 600 may comprise a first step 601 which consists in obtaining at least one operating parameter of the pump 30 on the basis of indications provided by the command and control device 121 of the pump 30, and in determining a required NPSH of the pump 30 as a function of this operating parameter or these operating parameters of the pump 30.

After step 601, the method continues to a step 602 which consists in determining a current filling level of the tank and in estimating future states of movement, which are future sea states and/or future states of movement of the ship. The current filling level of the tank is typically determined on the basis of a filling indication provided by the at least one filling level sensor 122 of the tank. The future sea states are estimated on the basis of meteorological information and of a course of the ship. The future states of movement of the ship may be estimated on the basis of future sea states, which are in turn estimated on the basis of meteorological information and of a course of the ship; as mentioned above, the evaluation of the corresponding movements of the ship on the basis of a given sea state is a familiar task in the evaluation of the seakeeping of a ship. The course of the ship is typically obtained on the basis of indications provided by the on-board systems of the ship, such as the speed of the ship and the heading of the ship. The meteorological information may be provided for example by terrestrial radiofrequency or satellite communication with a network of weather stations.

Optionally, a draft of the ship and/or a heading of the ship and/or a speed of the ship is also determined in step 602, typically on the basis of indications provided by the on-board systems of the ship. The draft of the ship is typically provided to the on-board systems of the ship by one or more sensors of the float and/or hydrostatic pressure type. The heading of the ship is typically provided to the on-board systems of the ship by one or more navigation compasses. The speed of the ship is typically provided to the on-board systems of the ship by an IMU and/or by a satellite navigation receiver of the GPS type.

After step 602, the method 600 continues to a third step 603 which consists in estimating the tripping risk parameter of the pump 30 with the aid of a predictive model stored in the memory associated with the central processing unit 110 or 210 or of the database 150. Step 603 is similar to step 403, and will therefore not be explained in detail again. As an alternative, the estimation of the tripping risk parameter of the pump 30 may be carried out in step 603 directly by simulation using a computational fluid dynamics method, by steps similar to steps 503A to 503C.

After step 603, the method 600 continues to a step 604 which consists in providing the user with an indication as a function of the tripping risk parameter estimated in step 603. Step 603 is similar to step 403 and will therefore not be explained in detail again.

Preferably, after step 604, the method 600 continues to a step 605 of aiding the decision intended to reduce the tripping risk parameter of the pump 30. This step 605 of aiding the decision may consist in a suggestion to change the direction or route of the ship, a change of heading, which is particularly suitable for stationary floating structures, a modification of the speed of the ship, or a change in the filling level of the tank or tanks (between the tanks or between a tank and a reservoir external to the ship, for the case of a stationary floating structure), or a modification of one or more operating parameters of the pump 30.

Some of the elements described above, especially the processing means, the central processing units, the data processing units and the control units, may be embodied in various forms, in a unitary or distributed fashion, by means of hardware and/or software components. Hardware components which may be used are ASIC application-specific integrated circuits, FPGA programmable logic arrays or microprocessors. Software components may be written in various programming languages, for example C, C++, Java (registered trademark) or VHDL. This list is not exhaustive.

Although the invention has been described in connection with several particular embodiments, it is very clear that it is in no way limited thereto and that it comprises all the technical equivalents of the means described as well as their combinations, if these fall within the scope of the invention as claimed.

Furthermore, it is very clear that a characteristic or a combination of characteristics described with reference to a method applies equally well to a corresponding system, and vice versa.

The use of the verb “have”, “comprise” or “include” and its conjugated forms does not exclude the presence of elements or steps other than those mentioned in a claim.

In the claims, any reference in parentheses should not be interpreted as a limitation of the claim.

1. A monitoring method carried out by a computer for monitoring the operation of a pump arranged in a tank for transporting a liquid product on board a ship, the pump having a pump-head arranged in the tank, the monitoring method comprising:
obtaining at least one operating parameter of the pump;
determining a required net positive suction head of the pump as a function of said at least one operating parameter of the pump;
determining a current filling level of the tank;
determining a current state of movement, which is a current sea state and/or a current state of movement of the ship; and
estimating a tripping risk parameter of the pump at least as a function of the required net positive suction head of the pump, of the current filling level of the tank and of the current state of movement, which have been determined in this way, and providing a user with an indication as a function of said tripping risk parameter.

2. The monitoring method as claimed in claim 1, wherein the step which consists in estimating a tripping risk parameter of the pump comprises:
simulating, by a computational fluid dynamics method, an evolution of the position of a free surface of the liquid inside the tank;
extracting from the results of the simulation an evolution of a height in the tank of the free surface at the pump-head; and
calculating the tripping risk parameter of the pump as a function of the evolution of said height and of the required net positive suction head of the pump.

3. The monitoring method as claimed in claim 1, wherein the step which consists in estimating a tripping risk parameter of the pump is performed with the aid of a predictive model trained by a supervised machine learning method over a training data set, the training data set being obtained on the basis of:
results of a plurality of tests, each test consisting in subjecting a test tank having a given filling level to movements and in measuring a height in the test tank of a free surface of the liquid at the pump-head, and/or
results of simulations, each consisting in simulating, by a computational fluid dynamics method, an evolution of the position of a free surface of the liquid within a tank model which has a given filling level and is subjected to movements, and in extracting from the results of the simulation an evolution of a height in the tank of the free surface of the liquid at the pump-head.

4. The monitoring method as claimed in claim 3, wherein at least one constraint is imposed on the predictive model during its training by the supervised machine learning method.

5. The monitoring method as claimed in claim 3, wherein the predictive model considers a plurality of pumps, the predictive model being capable of estimating a tripping risk parameter of each pump as a function of its position inside the ship.

6. The monitoring method as claimed in claim 1, wherein the tripping risk parameter of the pump comprises at least one among:
an occurrence probability of a situation in which a net positive suction head available at the pump-head is less than the required net positive suction head of the pump;
the maximum duration of a situation in which a net positive suction head available at the pump-head is less than the required net positive suction head of the pump;
the number of occurrences of a situation in which a net positive suction head available at the pump-head is less than the required net positive suction head of the pump;
the total time during which a net positive suction head available at the pump-head is less than the required net positive suction head of the pump;
an average duration of the situations in which a net positive suction head available at the pump-head is less than the required net positive suction head of the pump; and
an occurrence probability of a situation in which a net positive suction head available at the pump-head is less than the required net positive suction head of the pump for a duration greater than a predetermined duration.

7. The monitoring method as claimed in claim 1, furthermore comprising a step of aiding the decision intended to reduce the tripping risk parameter of the pump.

8. The monitoring method as claimed in claim 1, wherein the tank has a sump and the pump-head is arranged in said sump.

9. The monitoring method as claimed in claim 1, wherein the pump-head is arranged in proximity to a lower wall of the tank, and the pump-head is accommodated in a container located inside the tank, the container having a bottom which faces toward the lower wall of the tank and is provided with a passage placing the interior of the container in communication with the exterior of the container, an upper portion of the container, opposite the bottom of the container, having an opening in communication with the interior of the tank, the container furthermore having at least one mobile valve arranged to cooperate with a corresponding valve seat carried by the bottom of the container-Egg the valve being capable of obstructing the passage of the bottom of the container when a pressure difference exerted on the valve between the exterior of the container and the interior of the container is less than a determined positive threshold, and of freeing the passage when said pressure difference is greater than said threshold.

10. A monitoring system for monitoring the operation of a pump arranged in a tank for transporting a liquid product on board a ship, the pump having a pump-head arranged in the tank, the monitoring system comprising:
a command and control unit of the pump, which is capable of obtaining at least one operating parameter of the pump and of determining a required net positive suction head of the pump as a function of said at least one operating parameter of the pump;
at least one filling level sensor for measuring a current filling level of the tank;
a state of movement evaluation device capable of evaluating a current state of movement, which is a current sea state and/or a current state of movement of the ship; and
a processing means configured to estimate a tripping risk parameter of the pump at least as a function of the required net positive suction head of the pump, of the current filling level of the tank and of the current state of movement, which have been determined in this way, and to provide a user with an indication as a function of said tripping risk parameter.

11. A prediction method carried out by a computer for predicting the operation of a pump arranged in a tank for transporting a liquid product on board a ship, the pump having a pump-head arranged in the tank, the prediction method comprising:
obtaining at least one operating parameter of the pump;
determining a required net positive suction head of the pump as a function of said at least one operating parameter of the pump;
determining a current filling level of the tank;
estimating future states of movement, which are future sea states and/or future states of movement of the ship, on the basis of meteorological information and of a course of the ship; and
estimating a tripping risk parameter of the pump at least as a function of the required net positive suction head of the pump and of the current filling level of the tank, which have been determined in this way, of the course of the ship and of the future states of movement estimated in this way and providing a user with an indication as a function of said tripping risk parameter.

12. The prediction method as claimed in claim 11, wherein the step which consists in estimating a tripping risk parameter of the pump comprises:
simulating an evolution of the position of a free surface of the liquid inside the tank by a computational fluid dynamics method;
extracting from the results of the simulation an evolution of a height in the tank of the free surface at the pump-head; and
calculating the tripping risk parameter of the pump as a function of the evolution of said height and of the required net positive suction head of the pump.

13. The prediction method as claimed in claim 11, wherein the step which consists in estimating a tripping risk parameter of the pump is performed with the aid of a predictive model trained by a supervised machine learning method over a training data set, the training data set being obtained on the basis of:
results of a plurality of tests, each test consisting in subjecting a test tank having a given filling level to movements and in measuring a height in the test tank of a free surface of the liquid at the pump-head, and/or
results of simulations, each consisting in simulating, by a computational fluid dynamics method, an evolution of the position of a free surface of the liquid within a tank model which has a given filling level and is subjected to movements, and in extracting from the results of the simulation an evolution of a height in the tank of the free surface of the liquid at the pump-head.

14. The prediction method as claimed in claim 13, wherein the predictive model considers a plurality of pumps, the predictive model being capable of estimating a tripping risk parameter of each pump as a function of its position inside the ship.

15. The prediction method as claimed in claim 11, furthermore comprising a step of aiding the decision intended to reduce the tripping risk parameter of the pump along the course of the ship.

16. The prediction method as claimed in claim 11, wherein the tank has a sump and the pump-head is arranged in said sump.

17. The prediction method as claimed in claim 11, wherein the pump-head is arranged in proximity to a lower wall of the tank and the pump-head is accommodated in a container located inside the tank, the container having a bottom which faces toward the lower wall of the tank and is provided with a passage placing the interior of the container in communication with the exterior of the container, an upper portion of the container, opposite the bottom of the container, having an opening in communication with the interior of the tank, the container furthermore having at least one mobile valve arranged to cooperate with a corresponding valve seat carried by the bottom of the container, the valve being capable of obstructing the passage of the bottom of the container when a pressure difference exerted on the valve between the exterior of the container and the interior of the container is less than a determined positive threshold, and of freeing the passage when said pressure difference is greater than said threshold.

18. A prediction system for predicting the operation of a pump arranged in a tank for transporting a liquid product on board a ship, the pump having a pump-head arranged in the tank, the prediction system comprising:
a command and control unit of the pump, which is capable of obtaining at least one operating parameter of the pump and of determining a required net positive suction head of the pump as a function of said at least one operating parameter of the pump;
at least one filling level sensor for measuring a current filling level of the tank;
a state of movement estimation device capable of estimating future states of movement, which are future sea states and/or future states of movement of the ship, on the basis of meteorological information and of a course of the ship; and
a processing means configured to estimate a tripping risk parameter of the pump at least as a function of the required net positive suction head of the pump and of the current filling level of the tank, which have been determined in this way, of the course of the ship and of the future states of movement, which have been estimated in this way, and to provide a user with an indication as a function of said tripping risk parameter.
